(19) United States
(12) Patent Application Publication
(10) Pub. No.: US 2023/0389249 A1
(43) Pub. Date: Nov. 30, 2023

(54) COMPONENT MOUNTING DEVICE

(71) Applicant: FUJI CORPORATION, Chiryu (JP)

(72) Inventors: Mikako KAWASAKI, Chiryu-shi (JP); Ryosuke MORI, Kitanagoya-shi (JP)

(73) Assignee: FUJI CORPORATION, Chiryu (JP)

(21) Appl. No.: 18/325,353

(22) Filed: May 30, 2023

(30) Foreign Application Priority Data
May 30, 2022 (JP) 2022-087648

(51) Int. Cl. H05K 13/04; B25J 15/06

(52) U.S. Cl. CPC H05K 13/0409; B25J 15/0625

(57) ABSTRACT

Pickup of a component and pickup of a nozzle are appropriately performed while preventing an increase in size of a device. A component mounting device for picking up a nozzle configured to pick up a component through a negative pressure, at a holding section of a head through a negative pressure, includes: a nozzle flow path configured to supply a negative pressure generated by an operation of a vacuum pump to the nozzle; a positive pressure flow path configured to supply a positive pressure; an ejector configured to generate a negative pressure using the positive pressure of the positive pressure flow path; and a holding section flow path configured to supply the negative pressure generated by an operation of the ejector to the holding section.

### TECHNICAL FIELD

The present specification discloses a component mounting device.

### BACKGROUND ART

Conventionally, as a component mounting device, in a device that mounts a component on a substrate with a nozzle, a device that supplies a negative pressure used for a head to pick up and hold the nozzle and that supplies a negative pressure used for the nozzle to pick up the component has been proposed. For example, in a device of Patent Literature 1, a negative pressure from a pressure adjusting device is supplied to a nozzle holding mechanism that holds a nozzle, and a negative pressure from a nozzle pressure adjusting device is supplied to the nozzle.

### Patent Literature

Patent Literature 1: International Publication WO 2017/203626

### SUMMARY OF THE INVENTION

### Technical Problem

In Patent Literature 1 described above, in a case where a negative pressure pump is provided as a separate negative pressure source for each of the pressure adjusting device and the nozzle pressure adjusting device, not only the cost may increase but also the device may increase in size because a relatively large space is required. Therefore, a configuration in which one negative pressure pump is shared by the pressure adjusting device and the nozzle pressure adjusting device is also conceivable. However, in such a configuration, it is not preferable that, when a component in which leak is likely to occur is picked up, the nozzle may fall because the leak may affect the holding of the nozzle.

A main object of the present disclosure is to appropriately perform pickup of a component and pickup of a nozzle while preventing an increase in size of a device.

### Solution To Problem

The present disclosure employs the following means in order to achieve the above-described main object.

The gist of the component mounting device of the present disclosure is a component mounting device for picking up a nozzle configured to pick up a component through a negative pressure, at a holding section of a head through a negative pressure, the component mounting device including: a nozzle flow path configured to supply a negative pressure generated by an operation of a vacuum pump to the nozzle; a positive pressure flow path configured to supply a positive pressure; an ejector configured to generate a negative pressure using the positive pressure of the positive pressure flow path; and a holding section flow path configured to supply the negative pressure generated by an operation of the ejector to the holding section.

The component mounting device of the present disclosure includes the nozzle flow path configured to supply the negative pressure generated by the operation of the vacuum pump to the nozzle and the holding section flow path configured to supply the negative pressure generated by the operation of the ejector to the holding section. With this, since the negative pressures from separate negative pressure sources are supplied to the pickup of the component and the pickup of the nozzle, the pickup of the nozzle is not affected even in a case where leak occurs in the pickup of the component. In addition, by using the ejector as a first of the negative pressure sources, the configuration can be made compact and inexpensive as compared with a case where vacuum pumps are used as both the negative pressure sources. Further, since the negative pressure from the vacuum pump that can more stably supply the negative pressure than the ejector is used for the pickup of the component, the pickup of the component can be stabilized, and a component in which leak is likely to occur can be prevented from falling or the like. In these respects, it is possible to appropriately perform the pickup of the component and the pickup of the nozzle while preventing an increase in size of the device.

### BRIEF DESCRIPTION OF DRAWINGS

FIG. 1 is a perspective view schematically showing a configuration of component mounting device 10.

FIG. 2 is a block diagram showing an electrical connection relationship of component mounting device 10.

FIG. 3 is a block diagram showing a principal configuration for supplying pressure.

FIG. 4 is a configuration diagram schematically showing a configuration of pressure supply device 70.

### DESCRIPTION OF EMBODIMENTS

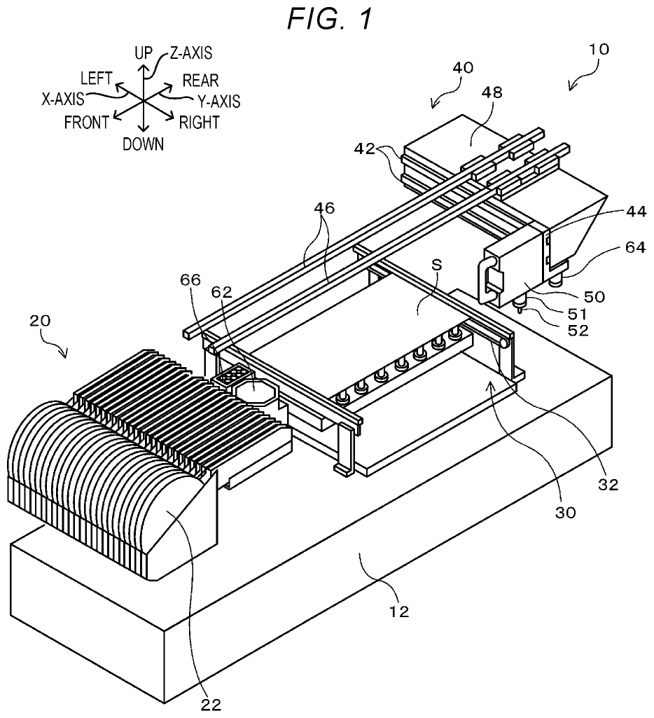

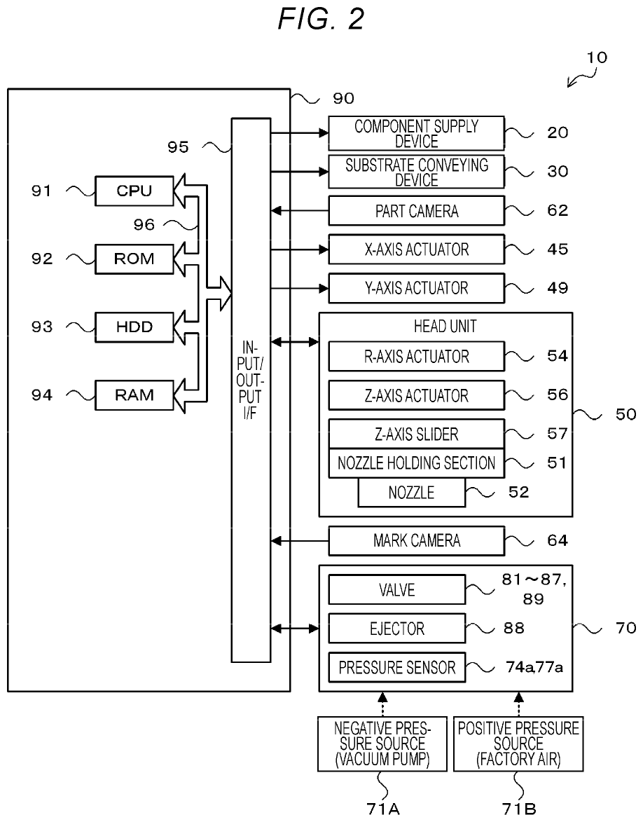

Next, an embodiment of the present disclosure will be described with reference to the drawings. FIG. 1 is a perspective view schematically showing a configuration of component mounting device 10. FIG. 2 is a block diagram showing an electrical connection relationship of component mounting device 10. In the present embodiment, a left-right direction in FIG. 1 is an X-axis direction, a front-rear direction is a Y-axis direction, and an up-down direction is a Z-axis direction.

As shown in FIG. 1, component mounting device 10 includes component supply device 20, substrate conveying device 30, moving device 40, head unit 50, part camera 62, mark camera 64, nozzle stocker 66, pressure supply device 70 (see FIG. 2), and control device 90 (see FIG. 2). Component supply device 20 is provided on a front portion of base 12 of component mounting device 10, is, for example, a tape feeder including reel 22 in which components are accommodated in a tape at predetermined intervals, and pulls out the tape from reel 22 through the drive of a motor (not shown) to supply the components to a supply position. Substrate conveying device 30 includes, for example, a pair of conveyor belts 32 provided on base 12 to be spaced apart from each other in the front-rear direction (Y-axis direction) and spanned in the left-right direction, and conveys substrate S from the left to the right in FIG. 1 by driving conveyor belts 32 through the drive of a motor (not shown). Moving device 40 includes guide rail 46 provided along the Y-axis direction, Y-axis slider 48 moving along guide rail 46, guide rail 42 provided on Y-axis slider 48 along the X-axis direction, and X-axis slider 44 moving along guide rail 42. Head unit 50 is attached to X-axis slider 44. Moving device 40 moves head unit 50 in the XY direction by moving X-axis slider 44 and Y-axis slider 48.

Head unit 50 is configured as, for example, a single nozzle head in which one nozzle 52 is attached onto an axial center line, and includes R-axis actuator 54 and Z-axis actuator 56 (see FIG. 2). Head unit 50 rotates nozzle 52 around the axial center line of head unit 50 through the drive of R-axis actuator 54. In addition, head unit 50 raises and lowers Z-axis slider 57 (see FIG. 2) in the Z-axis direction through the drive of Z-axis actuator 56. Nozzle holding section 51 (see FIG. 2) that holds nozzle 52 is provided at a lower end of Z-axis slider 57, and Z-axis slider 57 raises and lowers nozzle 52 in the Z-axis direction through the drive of Z-axis actuator 56. Nozzle 52 picks up a component at a nozzle tip using a negative pressure, or releases the component from the pickup using a positive pressure. Nozzle 52 is held at nozzle holding section 51 by a negative pressure. Pressure supply device 70 supplies a negative pressure and a positive pressure to nozzle holding section 51 and nozzle 52, and the details thereof will be described below.

Part camera 62 is provided between component supply device 20 and substrate conveying device 30. An imaging range is above part camera 62, and part camera 62 images a target object, such as a component picked up by nozzle 52, from below to generate a captured image.

Mark camera 64 is provided on a lower surface of X-axis slider 44. Mark camera 64 images a target object from above to generate a captured image. Examples of the target object of mark camera 64 include a component supplied from the tape feeder of component supply device 20, a mark affixed to substrate S, and a mark of nozzle 52 in nozzle stocker 66.

Nozzle stocker 66 is configured to accommodate multiple types of nozzles 52 having different sizes and shapes in respective accommodating sections. Nozzles 52 with which nozzle stocker 66 is stocked can be automatically exchanged for head unit 50. In addition, during the stop of the operation of component mounting device 10, the operator can take out a type of nozzle 52 unnecessary for a mounting process from among nozzles 52 with which nozzle stocker 66 is stocked, and cause nozzle stocker 66 to accommodate a type of nozzle 52 necessary for the mounting process.

As shown in FIG. 2, control device 90 is configured as a microprocessor centered on CPU 91 and includes ROM 92, HDD 93, RAM 94, input/output interface (I/F) 95, and the like in addition to CPU 91. These are connected via bus 96. Control device 90 causes component mounting device 10 to perform component mounting process based on a production job of substrate S acquired from a management device (not shown) or the like. The production job is data defining which components are mounted on substrate S in which order in component mounting device 10, how many substrates S on which the components are mounted in such a manner are to be manufactured, and the like.

In addition, control device 90 inputs image signals and the like from part camera 62 and mark camera 64 via input/output interface 95. X-axis slider 44, Y-axis slider 48, and Z-axis slider 57 are each provided with a position sensor (not shown), and control device 90 also inputs position information from those position sensors. In addition, control device 90 outputs drive signals and the like to component supply device 20, substrate conveying device 30, X-axis actuator 45 that moves X-axis slider 44, Y-axis actuator 49 that moves Y-axis slider 48, Z-axis actuator 56 that moves Z-axis slider 57, and pressure supply device 70, via input/output interface 95.

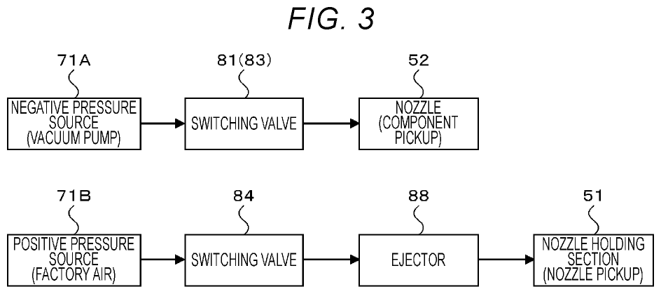

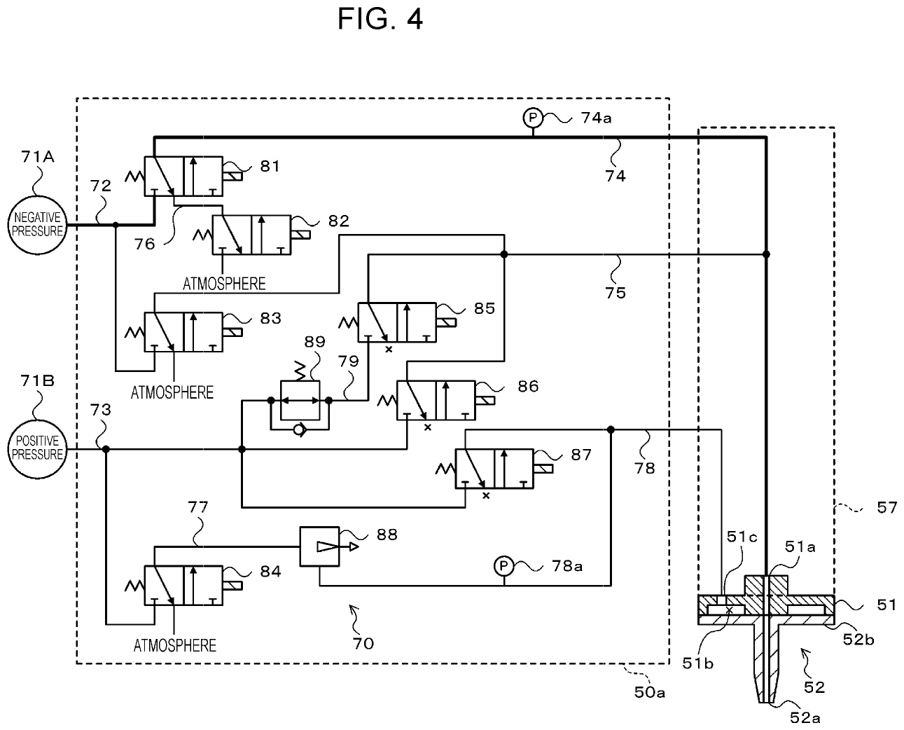

Hereinafter, pressure supply device 70 for supplying a negative pressure or a positive pressure to nozzle holding section 51 or nozzle 52 will be described. FIG. 3 is a block diagram showing a principal configuration for supplying pressure. FIG. 4 is a configuration diagram schematically showing a configuration of pressure supply device 70. In the present embodiment, as shown in FIG. 3, a negative pressure from the vacuum pump serving as negative pressure source 71A is supplied to nozzle 52 via switching valve 81 (83), whereby nozzle 52 is configured to pick up a component. The vacuum pump serving as negative pressure source 71A is provided in component mounting device 10. In addition, a positive pressure from a factory air serving as positive pressure source 71B is supplied to ejector 88 via switching valve 84, and a negative pressure generated by ejector 88 using the positive pressure is supplied to nozzle holding section 51, whereby nozzle holding section 51 is configured to pick up nozzle 52.

Here, as shown in FIG. 4, nozzle 52 picks up a component at suction port 52a provided at a tip (lower end) of a shaft portion having a tubular shape, and flange portion 52b is formed so as to protrude in a radial direction from an upper end of the shaft portion. In addition, nozzle holding section 51 is formed with center hole 51a provided at a lower end of Z-axis slider 57 and vertically penetrating a center portion, annular recessed portion 51b provided in a lower surface (holding surface) on which nozzle 52 is held, and communication hole 51c penetrating vertically so as to communicate from an upper surface to a bottom surface of recessed portion 51b. Recessed portion 51b of nozzle holding section 51 is covered with an upper surface of flange portion 52b of attached nozzle 52, thereby forming a negative pressure chamber. A negative pressure is supplied to the negative pressure chamber (into recessed portion 51b) via communication hole 51c, whereby nozzle holding section 51 can pick up and hold nozzle 52. In addition, a negative pressure is supplied to suction port 52a via center hole 51a of nozzle holding section 51 and the center hole of the shaft portion, whereby nozzle 52 can pick up and hold a component at suction port 52a. Although not shown, a permanent magnet is embedded in a part of the bottom surface of recessed portion 51b. In addition, a metal plate is embedded in a position of the upper surface (a held surface) of flange portion 52b of nozzle 52 facing the permanent magnet of recessed portion 51b. Therefore, nozzle 52 is held at nozzle holding section 51 by the suction force of the negative pressure and the suction force of the magnet.

Pressure supply device 70 includes multiple flow paths through which air of a positive pressure or a negative pressure flows, multiple switching valves 81 to 87 that switch the communication state of each flow path, ejector 88, and pressure reducing valve 89. Pressure supply device 70 includes, as main flow paths, negative pressure flow path 72, positive pressure flow path 73, large flow rate flow path 74, small flow rate flow path 75, connection flow path 76, ejector flow path 77, nozzle holding flow path 78, and reduced pressure flow path 79. In addition, pressure supply device 70 includes pressure sensor 74a that detects the pressure (negative pressure) in large flow rate flow path 74 and small flow rate flow path 75, and pressure sensor 78a that detects the pressure (negative pressure) in nozzle holding flow path 78, and outputs the detected pressure to control device 90. In the present embodiment, pressure supply device 70 (multiple switching valves 81 to 87, ejector 88, and pressure reducing valve 89) is provided inside head main body 50a of head unit 50, and each is operated based on a drive signal from control device 90. Further, a part of the flow path, for example, a part of large flow rate flow path 74, small flow rate flow path 75, and nozzle holding flow path 78 is configured to supply pressure to nozzle holding section 51 and nozzle 52 through Z-axis slider 57.

Negative pressure flow path 72 is a flow path communicating with negative pressure source 71A. Positive pressure flow path 73 is a flow path communicating with positive pressure source 71B. Large flow rate flow path 74 is a flow path communicating with center hole 51a of nozzle holding section 51 and supplying a negative pressure of a large flow rate to suction port 52a of nozzle 52 via center hole 51a. Small flow rate flow path 75 is a flow path communicating with large flow rate flow path 74 (center hole 51a of nozzle holding section 51) and supplying a negative pressure of a smaller flow rate than large flow rate flow path 74 to suction port 52a of nozzle 52. Large flow rate flow path 74 and small flow rate flow path 75 function as a negative pressure supply flow path for component pickup for supplying a negative pressure that is used for nozzle 52 to pick up the component. Small flow rate flow path 75 is configured as a flow path having a smaller diameter than large flow rate flow path 74 and has an inner diameter of, for example, about ⅓ to ½ of large flow rate flow path 74. Ejector flow path 77 is a flow path supplying a positive pressure to be caused to flow through ejector 88. Nozzle holding flow path 78 is a flow path communicating with communication hole 51c of nozzle holding section 51 and supplying the negative pressure generated by ejector 88 into recessed portion 51b via communication hole 51c. That is, nozzle holding section 51 functions as a negative pressure supply flow path for nozzle holding for supplying a negative pressure for holding (picking up) nozzle 52. Reduced pressure flow path 79 is a flow path through which air obtained by reducing the positive pressure of positive pressure flow path 73 by pressure reducing valve 89 flows.

Switching valve 81 switches between a state in which negative pressure flow path 72 and large flow rate flow path 74 communicate with each other and large flow rate flow path 74 and connection flow path 76 are shut off from each other and a state in which negative pressure flow path 72 and large flow rate flow path 74 are shut off from each other and large flow rate flow path 74 and connection flow path 76 communicate with each other. Switching valve 81 switches to a state in which negative pressure flow path 72 and large flow rate flow path 74 communicate with each other to supply the negative pressure from negative pressure source 71A to large flow rate flow path 74, whereby the negative pressure can be supplied to suction port 52a of nozzle 52. Switching valve 82 switches between a state in which connection flow path 76 is opened to the atmosphere and a state in which connection flow path 76 is shut off from the atmosphere. Switching valve 81 switches to a state in which large flow rate flow path 74 and connection flow path 76 communicate with each other and switching valve 82 switches to a state in which connection flow path 76 is opened to the atmosphere to supply the atmospheric pressure to large flow rate flow path 74, whereby the atmospheric pressure can be supplied to suction port 52a of nozzle 52.

Switching valve 83 switches between a state in which negative pressure flow path 72 and small flow rate flow path 75 communicate with each other and a state in which negative pressure flow path 72 and small flow rate flow path 75 are shut off from each other. Switching valve 83 switches to a state in which negative pressure flow path 72 and small flow rate flow path communicate with each other to supply the negative pressure from negative pressure source 71A to small flow rate flow path 75, whereby the negative pressure can be supplied to suction port 52a of nozzle 52. As will be described below, small flow rate flow path 75 is connected to switching valves 85 and 86. Therefore, in order to supply the negative pressure to nozzle 52 through small flow rate flow path 75, it is necessary for switching valves 85 and 86 to switch to a state in which connection between small flow rate flow path 75 and the other flow paths is shut off from each other.

Switching valve 84 switches between a state in which ejector flow path 77 communicates with positive pressure flow path 73 and a state in which ejector flow path 77 is opened to the atmosphere. Ejector 88 operates such that air of the positive pressure supplied from ejector flow path 77 flows at a high speed, thereby sucking the air in nozzle holding flow path 78. As a result, by supplying the negative pressure to nozzle holding flow path 78, the negative pressure can be supplied into recessed portion 51b via communication hole 51c of nozzle holding section 51.

Switching valve 85 switches between a state in which reduced pressure flow path 79 and small flow rate flow path 75 communicate with each other and a state in which reduced pressure flow path 79 and small flow rate flow path 75 are shut off from each other. Switching valve 86 switches between a state in which positive pressure flow path 73 and small flow rate flow path 75 communicate with each other and a state in which positive pressure flow path 73 and small flow rate flow path 75 are shut off from each other. As described above, in a case where switching valve 83 switches to a state in which negative pressure flow path 72 and small flow rate flow path communicate with each other, switching valve 85 switches to a state in which reduced pressure flow path 79 and small flow rate flow path 75 are shut off from each other, and switching valve 86 switches to a state in which positive pressure flow path 73 and small flow rate flow path 75 are shut off from each other. Switching valve 83 switches to a state in which negative pressure flow path 72 and small flow rate flow path 75 are shut off from each other, switching valve 85 switches to a state in which reduced pressure flow path 79 and small flow rate flow path 75 communicate with each other, and switching valve 86 switches to a state in which positive pressure flow path 73 and small flow rate flow path 75 are shut off from each other, whereby the reduced positive pressure is supplied from small flow rate flow path 75 to suction port 52a of nozzle 52. As a result, by releasing the component that has been picked up by nozzle 52 from the pickup, the component can be mounted on substrate S. In addition, switching valve 83 switches to a state in which negative pressure flow path 72 and small flow rate flow path 75 are shut off from each other, switching valve 85 switches to a state in which reduced pressure flow path 79 and small flow rate flow path are shut off from each other, and switching valve 86 switches to a state in which positive pressure flow path 73 and small flow rate flow path 75 communicate with each other, whereby the positive pressure of positive pressure source 71B can be supplied from small flow rate flow path to suction port 52a of nozzle 52. As a result, by supplying a relatively high positive pressure to nozzle 52, it is possible to remove clogging or the like of nozzle 52.

Switching valve 87 switches between a state in which positive pressure flow path 73 and nozzle holding flow path 78 communicate with each other and a state in which positive pressure flow path 73 and nozzle holding flow path 78 are shut off from each other. Switching valve 87 switches to a state in which positive pressure flow path 73 and nozzle holding flow path 78 communicate with each other to supply a positive pressure to nozzle holding flow path 78, whereby the positive pressure can be supplied into recessed portion 51b via communication hole 51c of nozzle holding section 51. As a result, nozzle 52 that has been picked up by nozzle holding section 51 can be released from the pickup.

In pressure supply device 70 of the present embodiment configured as described above, the negative pressure generated by ejector 88 using the positive pressure passing from positive pressure source 71B through positive pressure flow path 73 is supplied from nozzle holding flow path 78 to nozzle holding section 51 to hold nozzle 52. In addition, pressure supply device 70 supplies the negative pressure generated by negative pressure source 71A (negative pressure pump) to nozzle 52 from at least one of large flow rate flow path 74 and small flow rate flow path 75 through negative pressure flow path 72 to hold a component. Here, in a case where the component is picked up by nozzle 52, air leak need not be a problem as long as suction port 52a and the component are in close contact with each other. However, actually, in a case where it is difficult for suction port 52a to come into close contact with the component because of the shape of the component and the state of the upper surface, air leak is likely to occur. For example, in a component of which an upper surface has a hemispherical shape, such as an LED component, leak is likely to occur because a gap with a spherical surface increases depending on the pickup position. In addition, in a component including an operation section provided on an upper surface, such as a switch component, in a case where suction port 52a touches a level difference portion between the operation section and the periphery thereof, leak is likely to occur. In a case where the generation source and the supply flow path of the negative pressure used for the pickup of nozzle 52 and the pickup of the component are shared, the air leak caused by the pickup of the component may affect the pickup of nozzle 52 to decrease the pickup force (holding force), and nozzle 52 may fall. In pressure supply device 70 of the present embodiment, since the generation source and the supply flow path of the negative pressure used for the pickup of nozzle 52 and the pickup of the component are separately configured, it is possible to prevent the leak from affecting the pickup of nozzle 52.

In addition, as described above, in picking up (holding) the component, there is a probability of air leak depending on the component type, and a stable supply of the negative pressure is required in order to appropriately hold the component while allowing leak. Here, although ejector 88 is generally more compact in configuration and less expensive than the vacuum pump, the stability of the generated negative pressure is higher in the vacuum pump. Therefore, in order for ejector 88 to supply a necessary negative pressure flow rate equivalent to the vacuum pump, ejector 88 having a large body size is necessary, and mounting on head unit 50 (head main body 50a) is difficult. In addition, since the positive pressure flow rate supplied to ejector 88 increases, the consumption flow rate of component mounting device 10 may increase. Further, in a case where there is a unit operating using a positive pressure in component mounting device 10, since the positive pressure flow rate fluctuates every time the unit operates and the positive pressure supplied to ejector 88 is not stabilized, the negative pressure generated by ejector 88 is also not stabilized. In that respect, in pressure supply device 70 of the present embodiment, by using the negative pressure from the vacuum pump for the pickup of the component, the pickup of the component can be stably performed while preventing those problems from occurring. Therefore, even in a component in which leak is likely to occur, it is possible to stabilize the posture of the component during pickup and to appropriately mount the component.

Meanwhile, in holding nozzle 52 relative to the holding of the component, since the negative pressure chamber formed by nozzle holding section 51 (recessed portion 51b) of head unit 50 and the upper surface of flange portion 52b of nozzle 52 is in a sealed state, the leak rarely occurs. Therefore, nozzle 52 can be held at a small flow rate, so that a smaller ejector can be selected than in a case where ejector 88 is used for holding a component. In pressure supply device 70 of the present embodiment, since the negative pressure generated by ejector 88 is used for the pickup (holding) of nozzle 52, it is possible to make the device more compact and reduce the cost as compared with a case where vacuum pumps are provided for the pickup of the component and the pickup of nozzle 52, respectively. Further, since ejector 88 is provided in head main body 50a of head unit 50, it is possible to prevent an increase in length of nozzle holding flow path 78 as compared with a configuration in which ejector 88 is provided outside head main body 50a, for example, on base 12 of component mounting device 10, or the like. Therefore, since the negative pressure can be appropriately applied from ejector 88 to nozzle holding section 51 via nozzle holding flow path 78, the pickup of nozzle 52 can be stabilized. The suction force of the magnet is also used for the pickup of nozzle 52 (flange portion 52b). In these respects, even with the negative pressure generated by ejector 88, no problem may occur in picking up nozzle 52.

Further, pressure supply device 70 has two flow paths, that is, large flow rate flow path 74 and small flow rate flow path 75, as a negative pressure supply flow path for component pickup. In the present embodiment, in a case where a component is picked up by nozzle 52 having a relatively large diameter, switching valve 81 switches to a state in which negative pressure flow path 72 and large flow rate flow path 74 communicate with each other, and switching valve 83 switches to a state in which negative pressure flow path 72 and small flow rate flow path communicate with each other. With this, the negative pressure can be supplied to nozzle 52 having a large diameter from the two supply flow paths, that is, large flow rate flow path 74 and small flow rate flow path 75. Therefore, as compared with a case where the negative pressure is supplied from only large flow rate flow path 74, a negative pressure having a larger flow rate (maximum flow rate) can be supplied to nozzle 52 having a large diameter. In addition, in a case where a component is picked up by nozzle 52 having a relatively small diameter, switching valve 81 switches to a state in which negative pressure flow path 72 and large flow rate flow path 74 are shut off from each other and large flow rate flow path 74 and connection flow path 76 communicate with each other, and switching valve 83 switches to a state in which negative pressure flow path 72 and small flow rate flow path 75 communicate with each other. Switching valve 82 switches to a state in which connection flow path 76 is shut off from the atmosphere. With this, a small flow rate of negative pressure can be supplied from small flow rate flow path 75 to nozzle 52 having a small diameter.

Here, in a case where nozzle 52 having a large diameter is used, since the pressure drop when the leak occurs is relatively large even at a large flow rate, control device 90 can detect the presence or absence of a component picked up by nozzle 52 based on the detected value of pressure sensor 74a. On the other hand, in a case where nozzle 52 having a small diameter is used, since the pressure drop when the leak occurs is small when a negative pressure of a large flow rate is supplied, control device 90 need not be able to appropriately detect the presence or absence of the component based on the detected value of pressure sensor 74a. In that respect, in the present embodiment, in a case where nozzle 52 having a small diameter is used, a small flow rate of negative pressure is supplied from only small flow rate flow path 75, thereby facilitating the detection of the pressure drop when the leak occurs. As a result, even in a case where nozzle 52 having a small diameter is used, control device 90 can appropriately detect the presence or absence of the component based on the detected value of pressure sensor 74a. Further, in a case where nozzle 52 having a large diameter is used, the negative pressure is supplied from the two supply flow paths, that is, large flow rate flow path 74 and small flow rate flow path 75, to quickly reach the necessary negative pressure, so that the pickup of the component can be performed reliably and promptly.

Here, a correspondence relationship between elements of the present embodiment and elements of the present disclosure will be clarified. Large flow rate flow path 74 and small flow rate flow path 75 of the present embodiment correspond to the nozzle flow path of the present disclosure, ejector flow path 77 (positive pressure flow path 73) corresponds to the positive pressure flow path, ejector 88 corresponds to the ejector, and nozzle holding flow path 78 corresponds to the holding section flow path. Switching valves 81 and 83 correspond to the first switching section, and switching valve 84 corresponds to the second switching section. Head unit corresponds to the head, and moving device 40 corresponds to the moving section.

Component mounting device 10 of the above-described embodiment includes large flow rate flow path 74 and small flow rate flow path 75 that can supply the negative pressure generated by the operation of the vacuum pump to nozzle 52, and nozzle holding flow path 78 that can supply the negative pressure generated by the operation of ejector 88 to nozzle holding section 51. With this, even in a case where leak occurs because of the pickup of the component, it is possible to prevent the pickup of nozzle 52 from being affected. In addition, the configuration can be made compact and inexpensive as compared with a configuration in which vacuum pumps are used as both the negative pressure sources. Further, since the negative pressure from the vacuum pump is used for the pickup of the component, the pickup of the component can be stabilized, so that it is possible to prevent a component in which leak is likely to occur from falling or the like. In these respects, it is possible to appropriately perform the pickup of the component and the pickup of nozzle 52 while preventing an increase in size of the device.

In addition, since positive pressure flow path 73 is shared by the supply flow path of the positive pressure used for the pickup release of the component and the pickup release of nozzle 52 and by the supply flow path of the positive pressure used for ejector 88 to generate the negative pressure, the configuration can be made compact as compared with a configuration in which a positive pressure flow path dedicated to ejector 88 is provided.

In addition, by providing pressure supply device 70 in head unit 50 (head main body 50a), it is possible to suppress an increase in length of nozzle holding flow path 78, so that the supply of the negative pressure from ejector 88 to nozzle holding section 51 can be stabilized.

As a matter of course, the present disclosure is not limited to the above-described embodiment in any way and can be implemented in various aspects without departing from the technical scope of the present disclosure.

For example, in the above-described embodiment, head unit 50 includes (accommodates) pressure supply device 70; however, the configuration is not limited to this, and a part of the configuration of pressure supply device 70 (a part of switching valves 81 to 87, ejector 88, and pressure reducing valve 89) may be accommodated in X-axis slider 44, Y-axis slider 48, base 12 of component mounting device 10, or the like. However, in order for ejector 88 to more reliably apply the negative pressure, it is preferable to employ the configuration described in the embodiment.

In the embodiment, the positive pressure from positive pressure flow path 73 is shared for the pickup release of the component, the pickup release of nozzle 52, and the generation of the negative pressure by ejector 88; however, the configuration is not limited to this. Flow paths for separately supplying the positive pressure used for the pickup release of the component or the pickup release of nozzle 52, and the positive pressure used for the generation of a negative pressure by ejector 88 may be provided, respectively.

In the embodiment, large flow rate flow path 74 and small flow rate flow path 75 are provided as the negative pressure supply flow path for component pickup; however, the configuration is not limited to this, and only one flow path (for example, large flow rate flow path 74) may be provided.

In the embodiment, in a case where a component is picked up by nozzle 52 having a predetermined size or more, the negative pressure is supplied from both the flow paths, that is, large flow rate flow path 74 and small flow rate flow path 75; however, the configuration is not limited to this, and the negative pressure may be supplied from only large flow rate flow path 74.

In the embodiment, component mounting device 10 includes one vacuum pump as negative pressure source 71A; however, the configuration is not limited to this, and two vacuum pumps may be provided. For example, negative pressure source 71A may include two pumps, that is, a negative pressure pump connected to negative pressure flow path 72 to switching valve 81 and a negative pressure pump connected to the negative pressure flow path to switching valve 83. In such a case, negative pressure flow path 72 to switching valve 81 and the negative pressure flow path to switching valve 83 may be connected to each other or may be independent of each other.

Here, the component mounting device of the present disclosure may be configured as follows. For example, in the component mounting device of the present disclosure, a first switching section configured to switch between a state in which the vacuum pump and the nozzle flow path communicate with each other and communication between the positive pressure flow path and the nozzle flow path is shut off and a state in which communication between the vacuum pump and the nozzle flow path is shut off and the positive pressure flow path and the nozzle flow path communicate with each other and a second switching section configured to switch between a state in which the positive pressure flow path and the ejector communicate with each other and communication between the positive pressure flow path and the holding section flow path is shut off and a state in which communication between the positive pressure flow path and the ejector is shut off and the positive pressure flow path and the holding section flow path communicate with each other may be provided. With this, since the supply flow path of the positive pressure used for the pickup release of the component or the pickup release of the nozzle and the supply flow path of the positive pressure used for the ejector to generate the negative pressure can be shared, the configuration can be made compact as compared with a configuration in which a positive pressure flow path dedicated to the ejector is provided.

In the component mounting device of the present disclosure, at least a part of the nozzle flow path and the positive pressure flow path, the ejector, and the holding section flow path may be provided in the head, a moving section configured to move the head in a horizontal direction may be further provided, and a component picked up by the nozzle may be mounted on a substrate. By providing the ejector or the holding section flow path in the head, it is possible to suppress an increase in length of the holding section flow path and to stabilize the supply of the negative pressure from the ejector to the holding section.

### INDUSTRIAL APPLICABILITY

The present disclosure can be used for a manufacturing industry of component mounting devices, and the like.

### REFERENCE SIGNS LIST

10: component mounting device, 12: base, 20: component supply device, 22: reel, 30: substrate conveying device, 32: conveyor belt, 40: moving device, 42, 46: guide rail, 44: X-axis slider, 45: X-axis actuator, 48: Y-axis slider, 49: Y-axis actuator, 50: head unit, 50a: head main body, 51: nozzle holding section, 51a: center hole, 51b: recessed portion, 51c: communication hole, 52: nozzle, 52a: suction port, 52b: flange portion, 54: R-axis actuator, 56: Z-axis actuator, 57: Z-axis slider, 62: part camera, 64: mark camera, 66: nozzle stocker, 70: pressure supply device, 71A: negative pressure source, 71B: positive pressure source, 72: negative pressure flow path, 73: positive pressure flow path, 74: large flow rate flow path, 74a, 78a: pressure sensor, 75: small flow rate flow path, 76: connection flow path, 77: ejector flow path, 78: nozzle holding flow path, 79: reduced pressure flow path, 81 to 87: switching valve, 88: ejector, 89: pressure reducing valve, 90: control device, 91: CPU, 92: ROM, 93: HDD, 94: RAM, 95: input/output interface, 96: bus, S: substrate

1. A component mounting device for picking up a nozzle configured to pick up a component through a negative pressure, at a holding section of a head through a negative pressure, the component mounting device comprising:
a nozzle flow path configured to supply a negative pressure generated by an operation of a vacuum pump to the nozzle;
a positive pressure flow path configured to supply a positive pressure;
an ejector configured to generate a negative pressure using the positive pressure of the positive pressure flow path; and
a holding section flow path configured to supply the negative pressure generated by an operation of the ejector to the holding section.

2. The component mounting device according to claim 1, further comprising:
a first switching section configured to switch between a state in which the vacuum pump and the nozzle flow path communicate with each other and communication between the positive pressure flow path and the nozzle flow path is shut off and a state in which communication between the vacuum pump and the nozzle flow path is shut off and the positive pressure flow path and the nozzle flow path communicate with each other; and
a second switching section configured to switch between a state in which the positive pressure flow path and the ejector communicate with each other and communication between the positive pressure flow path and the holding section flow path is shut off and a state in which communication between the positive pressure flow path and the ejector is shut off and the positive pressure flow path and the holding section flow path communicate with each other.

3. The component mounting device according to claim 1,
wherein at least a part of the nozzle flow path and the positive pressure flow path, the ejector, and the holding section flow path are provided in the head,
the component mounting device further comprises a moving section configured to move the head in a horizontal direction, and
the component picked up by the nozzle is mounted on a substrate.
